(19) United States
(12) Patent Application Publication
(10) Pub. No.: US 2025/0343560 A1
(43) Pub. Date: Nov. 6, 2025

(54) OPTIMIZED VITERBI DECODING FOR UWB COMMUNICATIONS

(71) Applicant: STMicroelectronics International N.V., Geneva (CH)

(72) Inventor: Philippe GRAFFOULIERE, Voreppe (FR)

(21) Appl. No.: 19/194,478

(22) Filed: Apr. 30, 2025

(30) Foreign Application Priority Data
May 2, 2024 (FR) FR2404623

(51) Int. Cl. H03M 13/41; H03M 13/11; H03M 13/23

(52) U.S. Cl. CPC H03M 13/41; H03M 13/1125; H03M 13/23

(57) ABSTRACT

An optimized Viterbi decoding for UWB communications is provided. In an example, a receiver receives pulse trains encoding a plurality of bits using a convolutional code {3, 2, 5}, the systematic g₀ and parity g₁ bits of which are mapped into two bitstreams respectively depending on g₀\hat{ }g₁ and g₁. Noting that convolutional coding and mapping lead to modulation (b.z−1\hat{ }b\hat{ }b.z+1, b.z−1\hat{ }b.z+1\hat{ }b.z−1\hat{ }b.z+1), a demodulator demodulates the pairs of received pulse trains into respective pairs of LLR values and a Viterbi decoder built on a convolutional code decodes {3, 7, 5} each pair of LLR values into one decoded bit.

### CROSS REFERENCE TO RELATED APPLICATION(S)

This application claims the priority benefit of French patent application number 2404623, filed on May 2, 2024, entitled “DECODAGE VITERBI OPTIMISE POUR COMMUNICATIONS ULB”, which is hereby incorporated by reference to the maximum extent allowable by law.

### TECHNICAL FIELD

Embodiments relating to the field of data transmission and more specifically decoding data using a Viterbi decoder.

### BACKGROUND

Ultra Wideband UWB data transmission uses very short radio frequency pulses (often less than a nanosecond), over a large bandwidth of the order of 500 MHz or more. Ultra Wideband UWB communications operate at frequencies ranging between 3.1 GHz and 10.6 GHz, for example in a first band between 3.1 GHz and 4.8 GHz or a second band between 6 GHz and 8.5 GHz.

The bits to be transmitted (from the PHY header, denoted PHR, and the PSDU payload) are conventionally encoded using the systematic convolutional encoder 110 shown in FIG. 1. This convolutional encoder is called {3, 2, 5} because of its constraint length K=3 and its generator polynomials g₀=[010](i.e. 2) and g₁=[101](i.e. 5). It has a code rate R of ½.

In practice, each bit to be transmitted is transmitted using a train of pulses modulated using BPSK (binary phase shift keying) with a repetition frequency of 124.8 or 249.6 MHz. FIG. 2 defines, for example, the bitstreams corresponding to the pulses to be transmitted, as a function of the systematic bit g₀ and the parity bit g₁ obtained at the output of the convolutional encoder. Table 20 at the top defines the bitstreams for a repetition frequency PRF of 124.8 MHz, and Table 20′ at the bottom for a PRF of 249.6 MHz.

These tables show that the first bitstream does not only depend on g₀ but also on g₁, whilst the second bitstream to be transmitted only depends on g₁. More specifically, the first bitstream is a function of g₀\hat{ }g₁ (\hat{ } being the EXCLUSIVE OR operator). In other words, it is not (g₀, g₁) which is modulated, but (g₀\hat{ }g₁, g₁).

On the receiver side, decoding thus involves inverse mapping to find the systematic bit, denoted b₀, from the two trains of pulses received (r₀, r₁): b₀=ABS (r₁−r₀)−ABS (r₁+r₀), the parity bit, denoted b₁, being obtained directly from the second train of pulses received: b₁=r₁. A Viterbi decoder built on the systematic convolutional code {3, 2, 5} of the encoder is then used to decode each transmitted bit from the decoded pairs (b₀, b₁).

It is recognised that this decoding is not optimal.

On the one hand, the decoding distance of the systematic bit b₀ is halt that of the parity bit b₁. The error rate on b₀ is therefore higher than on b₁.

On the other hand, the soft-decision decoding of a Viterbi algorithm would be under-utilised because of the hard-decision decoding of the inverse mapping.

There is therefore a need for improved decoding of such signals formed by pulse trains encoding a plurality of bits using the convolutional code {3, 2, 5}, the systematic and parity bits (g₀, g₁) of which are mapped into two bitstreams respectively depending on g₀\hat{ }g₁ and g₁.

### BRIEF SUMMARY

Noting that convolutional coding on the bit b to be transmitted and mapping lead to modulation (b.z−1\hat{ }b\hat{ }b.z+1, b.z−1\hat{ }b.z+1, b.z−1\hat{ }b.z+1), the coding and modulation operations can be assimilated to the non-systematic convolutional code {3, 7, 5}, i.e. based on the generator polynomials g₀=[111](i.e. 7) and g₁=[101](i.e. 5).

According to one aspect, a communication device is proposed comprising:
a receiver configured to receive a signal formed by pulse trains encoding a plurality of bits using a convolutional code {3, 2, 5}, the systematic and parity bits (g₀, g₁) of which are mapped into two bitstreams respectively depending on g₀\hat{ }g₁ and g₁, a demodulator configured to demodulate pairs of received pulse trains (r₀, r₁) into respective pairs of bit values (b₀, b₁), and a Viterbi decoder built on a convolutional code {3, 7, 5}, configured to decode each pair of bit values into one decoded bit.

In this way, decoding no longer requires an inverse mapping step. The bit values at the input of the Viterbi decoder are obtained from the pulse trains with the same reliability. This improves decoding.

A communication system comprising a transmitter and a receiver connected to a same communication channel is also proposed, the transmitter comprising:
a convolutional encoder with convolutional code {3, 2, 5} configured to encode a plurality of bits into respective pairs of systematic and parity bits (g₀, g₁),
a symbol mapper configured to map each pair of systematic and parity bits (g₀, g₁) into a pair of bitstreams respectively depending on g₀\hat{ }g₁ and g₁,
a modulator-transmitter configured to modulate and transmit each bitstream as a pulse train on the communication channel, and the receiver being a communication device as defined above, to receive and decode a signal formed by the pulse trains.

According to a second aspect, a communication method comprising the following steps is proposed:
receiving a signal formed by pulse trains encoding a plurality of bits using a convolutional code {3, 2, 5}, the systematic and parity bits (g₀, g₁) of which are mapped into two bitstreams respectively depending on g₀\hat{ }g₁ and g₁,
demodulating pairs of received pulse trains (r₀, r₁) into respective pairs of bit values (b₀, b₁), and
decoding each pair of bit values into one decoded bit using a Viterbi decoder built on a convolutional code {3, 7, 5}.

The method has the same advantages as those of the aforementioned device.

Optional features of embodiments are defined in the appended claims. Some of these features are explained below with reference to a device, while they can be translated into method features.

In one embodiment, the bit values comprise log-likelihood ratios. Soft demodulation is then used.

Of course, hard demodulation can alternatively be used.

In another embodiment, the first bit value of a pair of bit values comprises a log-likelihood ratio associated with the first pulse train of a pair of received pulse trains, and the second bit value of the pair of bit values comprises a log-likelihood ratio associated with the second pulse train of the pair of received pulse trains. In this way, b₀=r₀, b₁=r₁.

Soft-decision Viterbi decoding can then be fully utilised. Decoding is thus optimal, with in particular an estimated gain of 1.8 dB (in error rate) without any additional complexity.

### BRIEF DESCRIPTION OF THE DRAWINGS

Other advantages and features of the present disclosure will become apparent upon examining the detailed description of non-limiting embodiments and implementations, and from the accompanying drawings, wherein:

FIG. 1,

FIG. 2,

FIG. 3,

FIG. 4,

FIG. 5,

FIG. 6,

FIG. 7, and

FIG. 8 schematically show implementations and embodiments of the present disclosure.

### DETAILED DESCRIPTION

FIG. 3 shows a communication system 100, at the physical layer PHY, comprising a transmitter 102 and a receiver 104. The transmitter 102 comprises a data source 106, typically PHY service data units (PSDUs) received from the higher layers (not shown) of the transmitter 102. A Reed-Solomon 108 encoder encodes the PSDUs to introduce redundancy.

These encoded coded PSDU data and a PHY header (denoted PHR) are then supplied as input to a convolutional encoder 110, which produces data symbols. The input bits are denoted b⁽ⁿ⁾.

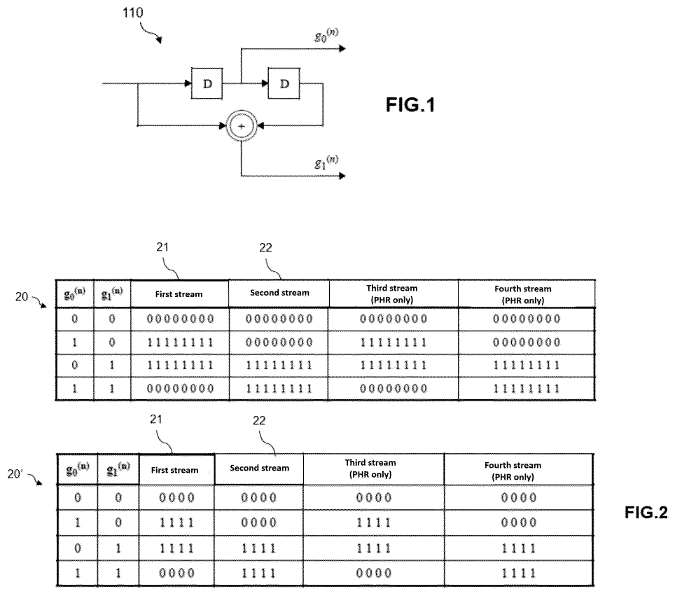

The convolutional encoder 110 is systematic of type {3, 2, 5} as shown in FIG. 1: K=3 and the generator polynomials are g₀=[010](i.e. 2) and g₁=[101](i.e. 5).

The convolutional encoder with convolutional code {3, 2, 5}encodes a plurality of bits into respective pairs of systematic and parity bits. In other words, each bit b⁽ⁿ⁾ produces a systematic bit g₀⁽ⁿ⁾ and a parity bit g₁⁽ⁿ⁾, forming a data symbol (g₀⁽ⁿ⁾, g₁⁽ⁿ⁾).

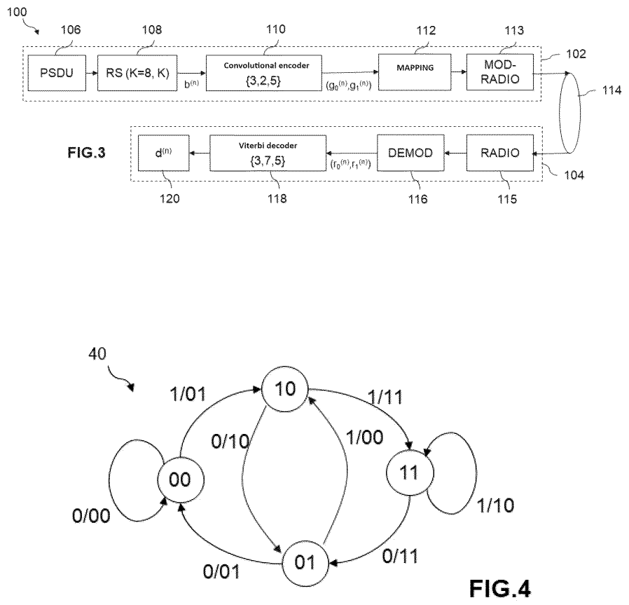

FIG. 4 schematically shows a state diagram 40 of the convolutional encoder 110 showing the four possible states “00”, “01”, “10” and “11” and the possible transitions given a new input bit b⁽ⁿ⁾. For example, 1/01 indicates that the transition from the state “00” to the state “10” is carried out when the input bit b⁽ⁿ⁾ is 1 and the output of the convolutional encoder 110, i.e. (g₀⁽ⁿ⁾, g₁⁽ⁿ⁾) is “01”.

A mapping block 112 then converts the data symbols (g₀⁽ⁿ⁾, g₁⁽ⁿ⁾) into bitstreams in preparation for the transmission of pulse trains on a transmission channel 114.

Each symbol (g₀⁽ⁿ⁾, g₁⁽ⁿ⁾) generates two bitstreams 21, 22 (except for the PHR where four streams are generated) in accordance with Tables 20, 20′ in FIG. 2, according to the mode chosen between the PRF mode of 124.8 MHz and the PRF mode of 249.6 MHz. It should be noted that while these frequencies are the average frequencies, the 124.8 MHz mode has a peak PRF of 249.6 MHz for an output rate of 6.81 Mbits/s, whilst the 249.6 MHz mode has a peak PRF of 499.2 MHz for an output rate of 27.24 Mbits/s.

The mapping block 112 thus performs symbol mapping configured to map each pair of systematic and parity bits (g₀, g₁) into a pair of bitstreams. This mapping is not a simple mapping between the first bit of the symbol and the first bitstream, and a simple mapping between the second bit of the symbol and the second bitstream, but a more complex mapping. In particular, the first bitstream depends on the two bits of the symbol, in particular on g₀\hat{ }g₁ (EXCLUSIVE OR). The second bitstream remains a function of g₁ only.

A modulation-transmission block 113 then modulates the bitstreams so that they are adapted to transmission on a transmission channel 114. BPSK (binary phase shift keying) is used.

Each of the two (or four) bitstreams 20, 21 is transmitted by the radio block 113, on the transmission channel 114, in the form of a BPSK pulse train. The (four) pulse trains are separated by a guard interval.

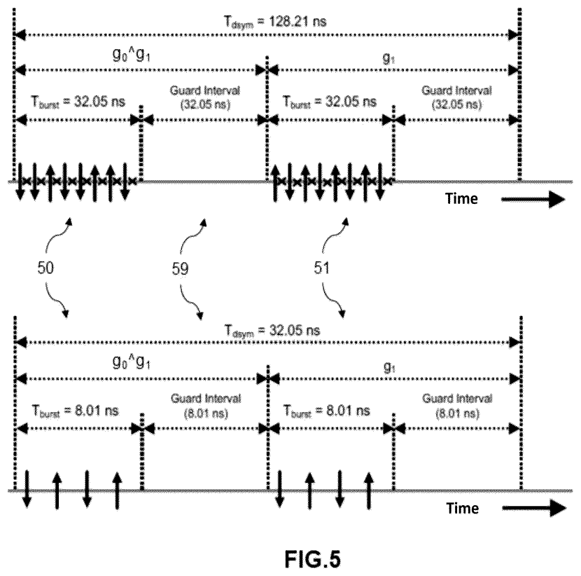

FIG. 5 schematically shows the pulse trains 50, 51, separated by a guard interval 59 of the same length, during the modulation of a PSDU symbol (g₀, g₁) in the 124.8 MHz mode (two trains with eight pulses each at the top) and in the 249.6 MHz mode (two trains with four pulses each at the bottom).

The transmission channel 114 is, for example, a wireless channel in the frequency band ranging from 3.1 GHz to 10.6 GHz, preferably in the band 3.1 GHz-4.8 GHz or in the band 6 GHz-8.5 GHz. The transmission channel 114 is typically defined with a bandwidth of 499.2 MHz, 500 MHz or greater.

The receiver 104 comprises a demodulator block 116, which receives the signal from the channel 114, for example via a Rake receiver 115, and demodulates (BPSK) the signal to recover the transmitted bitstreams and determine confidence or “log-likelihood ratio” (LLR) values corresponding to the received data symbols, denoted o⁽ⁿ⁾, in this case a pair of received pulse trains. The two bitstreams for each pair o⁽ⁿ⁾ of received pulse trains are denoted r₀⁽ⁿ⁾ and r₁⁽ⁿ⁾. For the sake of simplicity, the associated LLR values are also denoted r₀⁽ⁿ⁾ and r₁⁽ⁿ⁾ (and more generally r₀ and r₁). Also, o⁽ⁿ⁾=(r₀⁽ⁿ⁾, r₁⁽ⁿ⁾).

In an alternative embodiment, the demodulator block 116 supplies hard bits (either 0 or 1) rather than LLR values.

Subsequently, the index n can be omitted for the sake of simplicity when processing a symbol o=(r₀, r₁).

The received symbols o⁽ⁿ⁾, i.e. the LLR values r₀⁽ⁿ⁾ and r₁⁽ⁿ⁾, are successively supplied to a channel decoder 118 which performs channel decoding, in this example using a decoder with a soft-input Viterbi algorithm to recover the initial encoded data b⁽ⁿ⁾.

The inputs to the Viterbi decoder are denoted b₀ and b₁. b₀=r₀ and b₁=r₁ meaning that there is no pre-processing of the LLRs obtained from the demodulator block 116, in particular no inverse mapping of that carried out by the modulator block 112 on the basis of Tables 20, 20′ in FIG. 2.

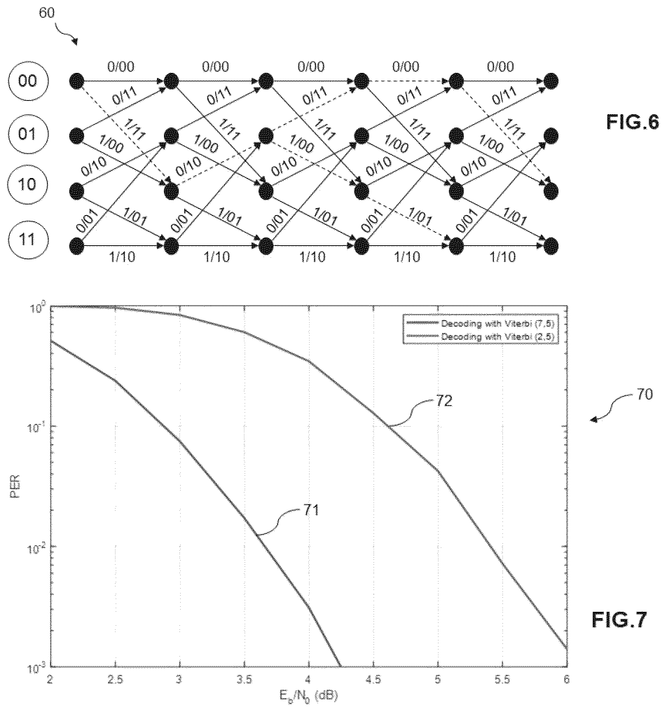

FIG. 6 shows a trellis diagram 60 corresponding to the decoding symbols initially encoded by a finite state machine different from that shown in FIG. 1 (and therefore from the transmitter 102). Given that the convolutional coding on a bit b to be transmitted and the mapping shown in FIG. 2 lead to modulation (b.z−1\hat{ }b\hat{ }b.z+1, b.z−1\hat{ }b.z+1, b.z−1\hat{ }b.z+1), these coding and modulation operations are considered, in a unitary manner, by the receiver 104: they therefore correspond to non-systematic convolutional coding {3, 7, 5}, i.e. based on the generator polynomials g₀=[111](i.e. 7) and g₁=[101](i.e. 5).

In addition, the trellis diagram 60 in FIG. 6 is that of a finite state machine corresponding to the non-systematic convolutional encoder {3, 7, 5}. The four states “00”, “01”, “10” and “11” are represented in each of the six columns, provided with interconnection arrows to represent all the possible paths between states during five successive state transitions corresponding to five symbols o⁽ⁿ⁻⁴⁾ to o⁽ⁿ⁾ obtained. In this example, for each of the four states, there is a choice of two distinct subsequent states. As shown for the transition from the left-hand column of states to the adjacent column of states, each state transition corresponds to a different received symbol.

The dashed lines in the figure represent the most likely state transitions for illustrative purposes only, keeping one path per sate, and show that after a certain number L of transitions, in this example five transitions, the likely paths merge into a single path. Using this principle, the data bits b⁽ⁿ⁾ can be decoded with a delay of L symbol periods.

The bits 120 decoded in this way are denoted d⁽ⁿ⁾ in the figure.

FIG. 7 is a graph 70 showing the gain of 1.8 dB obtained by using a Viterbi decoder built on a convolutional code {3, 7, 5}(curve 71), rather than the conventional approach of inverse mapping shown in FIG. 2 to recover g₀ and g₁ then the use of a Viterbi decoder built on a convolutional encoding code, i.e. {3, 2, 5}(curve 72). This gain is also accompanied by a simplification of the complexity (absence of inverse mapping) at no additional computational cost (similar use of a Viterbi decoder).

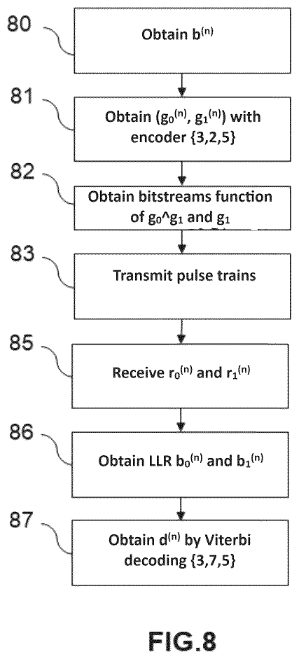

Finally, FIG. 8 is a flowchart showing steps of a communication method.

In step 80, the transmitter 102 obtains bits b⁽ⁿ⁾ to be transmitted, preferably the PSDU data encoded by a Reed-Solomon encoder and the PHR header.

In step 81, the bits are encoded by the convolutional encoder 110 of type {3, 2, 5} to obtain (g₀⁽ⁿ⁾, g₁⁽ⁿ⁾).

In step 82, bitstreams are obtained from (g₀⁽ⁿ⁾, g₁⁽ⁿ⁾) using one of the tables shown in FIG. 2.

In step 83, the bitstreams are transmitted as pulse trains using BPSK modulation.

The rest of the method takes place on the receiver 104 side.

In step 85, the receiver 104 receives pulse trains r₀⁽ⁿ⁾ and r₁⁽ⁿ⁾.

In step 86, log-likelihood ratio values LLR b₀⁽ⁿ⁾ and b₁⁽ⁿ⁾ are obtained for the pulse trains.

In step 87, these values b₀⁽ⁿ⁾ and b₁⁽ⁿ⁾ are decoded by a Viterbi decoder built on non-systematic convolutional coding {3, 7, 5} so as to obtain the decoded bits d⁽ⁿ⁾ corresponding to the initial data bits b⁽ⁿ⁾.

The transmitted data b⁽ⁿ⁾ can be used for operations such as access control (to a building, vehicle, IT system, etc.), location operations and equipment control operations (typically home automation).

1. A communication device comprising:
a receiver configured to receive a signal formed by pulse trains encoding a plurality of bits using a convolutional code {3, 2, 5}, a systematic g₀ bit and a parity g₁ bit of which are mapped into two bitstreams respectively depending on g₀\hat{ }g₁ and g₁;
a demodulator configured to demodulate pairs of received pulse trains into respective pairs of bit values; and
a Viterbi decoder built on a convolutional code {3, 7, 5}, configured to decode each pair of bit values into one decoded bit.

2. The communication device of claim 1, wherein the bit values of the pairs of bit values comprise log-likelihood ratios.

3. The communication device of claim 1, wherein a first bit value of a pair of bit values comprises a log-likelihood ratio associated with a first pulse train of a pair of received pulse trains, and a second bit value of the pair of bit values comprises a log-likelihood ratio associated with a second pulse train of the pair of received pulse trains.

4. A communication system comprising a transmitter and a receiver connected to a same communication channel, wherein the transmitter comprises:
a convolutional encoder with convolutional code {3, 2, 5} configured to encode a plurality of bits into respective pairs of systematic g₀ and parity g₁ bits;
a symbol mapper configured to map each pair of systematic g₀ and parity g₁ bits into a pair of bitstreams respectively depending on g₀\hat{ }g₁ and g₁; and
a modulator-transmitter configured to modulate and transmit each bitstream as a pulse train on the communication channel, and the receiver being a communication device of claim 1, to receive and decode a signal formed by the pulse trains.

5. A communication method comprising:
receiving a signal formed by pulse trains encoding a plurality of bits using a convolutional code {3, 2, 5}, a systematic g₀ bit and a parity g₁ bit of which are mapped into two bitstreams respectively depending on g₀\hat{ }g₁ and g₁;
demodulating pairs of received pulse trains into respective pairs of bit values; and
decoding each pair of bit values into one decoded bit using a Viterbi decoder built on a convolutional code {3,7,5}.
